(19) United States
(12) Patent Application Publication
(10) Pub. No.: US 2025/0107171 A1
(43) Pub. Date: Mar. 27, 2025

(54) SEMICONDUCTOR SUBSTRATE AND METHOD OF MANUFACTURING THE SAME

(71) Applicant: Proterial, Ltd., Tokyo (JP)

(72) Inventors: Sadahiko KONDO, Tokyo (JP); Akito TOMINAMI, Tokyo (JP)

(21) Appl. No.: 18/884,400

(22) Filed: Sep. 13, 2024

(30) Foreign Application Priority Data
Sep. 27, 2023 (JP) 2023-166161

(51) Int. Cl. H01L 29/06; H01L 21/02; H01L 21/66; H01L 29/16; H01L 29/78

(52) U.S. Cl. CPC H10D 62/117; H01L 21/02378; H01L 21/02529; H10D 62/8325; H01L 22/22; H10D 30/64

(57) ABSTRACT

A method of manufacturing a semiconductor substrate includes (a) preparing a substrate having a front surface, a back surface located on an opposite side of the front surface, a first sloped portion connected to the front surface, and a second sloped portion connected to the back surface, (b) forming an epitaxial layer on the front surface and the first sloped portion, (c) after the (b), polishing the back surface, and (d) after the (c), grinding the first sloped portion.

### CROSS-REFERENCE TO RELATED APPLICATION

This application claims foreign priority benefits under 35 U.S.C. § 119 to Japanese Patent Application No. 2023-166161 filed on Sep. 27, 2023, the content of which is hereby incorporated by reference in its entirety.

### TECHNICAL FIELD

The present invention relates to a semiconductor substrate and a manufacturing technique thereof, and relates to, for example, a technique effectively applied to a semiconductor substrate having sloped portions at its edge and a manufacturing technique thereof.

### BACKGROUND

Japanese Unexamined Patent Application Publication No. 2020-11853 (Patent Document 1) describes a technique capable of suppressing the occurrence of cracking, chipping, or the like during the process of reclaiming a silicon carbide epitaxial substrate.

### SUMMARY

For example, during the processing for a substrate, cracking, chipping, or the like is likely to occur at the edge of the substrate. For this reason, a sloped portion referred to as “beveling portion” is formed at the edge of the substrate, thereby suppressing the occurrence of cracking or chipping at the edge of the substrate.

In this respect, the inventors of this application have found that simply forming the “beveling portion” is not sufficient from the viewpoint of reducing the occurrence of failures in semiconductor devices formed on the substrate. Therefore, further ingenuity is desired in order to reduce the failures in semiconductor devices.

A semiconductor substrate according to one embodiment includes a first main surface, a second main surface located on an opposite side of the first main surface, a first sloped portion connected to the first main surface, and a second sloped portion connected to the second main surface. Here, a surface roughness of the first sloped portion is lower than a surface roughness of the second sloped portion.

A method of manufacturing a semiconductor substrate according to one embodiment includes (a) preparing a substrate having a first main surface, a second main surface located on an opposite side of the first main surface, a first sloped portion connected to the first main surface, and a second sloped portion connected to the second main surface, (b) forming an epitaxial layer on the first main surface and the first sloped portion, (c) after the (b), polishing the second main surface, and (d) after the (c), grinding the first sloped portion.

According to one embodiment, it is possible to provide a substrate capable of reducing the failures in semiconductor devices.

### BRIEF DESCRIPTIONS OF THE DRAWINGS

FIG. 1 is a diagram illustrating a manufacturing process of a reclaimed substrate according to an embodiment.

FIG. 2 is a diagram illustrating the manufacturing process of the reclaimed substrate subsequent to FIG. 1.

FIG. 3 is a diagram illustrating the manufacturing process of the reclaimed substrate subsequent to FIG. 2.

FIG. 4 is a diagram illustrating the manufacturing process of the reclaimed substrate subsequent to FIG. 3.

FIG. 5 is a diagram illustrating the manufacturing process of the reclaimed substrate subsequent to FIG. 4.

FIG. 6 is a diagram illustrating a structure of the reclaimed substrate.

FIG. 7 is a graph illustrating a relationship between a slope angle of a sloped portion and a thickness of the reclaimed substrate.

### DETAILED DESCRIPTION

In all of the drawings for describing the embodiment, the same members are denoted by the same reference characters in principle and repetitive descriptions thereof will be omitted. Note that hatching is applied in some cases even in plan views for making the drawings easily understood.

### Wide Band Gap Semiconductor Material

For example, inverter circuits are used as circuits for controlling motors in automobiles and home appliances. Power semiconductor elements such as metal oxide semiconductor field effect transistors (MOSFETs) and insulated gate bipolar transistor (IGBTs) are used in these inverter circuits.

Such power semiconductor elements are required to have low on-resistance, low switching loss, and the like in addition to high withstand voltage. Here, the current mainstream of power semiconductor elements is a field effect transistor formed on a semiconductor substrate whose main component is silicon, but this power semiconductor element is approaching its theoretical performance limit.

In this respect, semiconductor elements (hereinafter referred to as wide band gap power semiconductor elements) including field effect transistors formed on a semiconductor substrate whose main component is a semiconductor material with a larger band gap than that of silicon have been attracting attention.

This is because a large band gap means that the material has a high dielectric breakdown strength, making it easier to achieve a high withstand voltage.

Further, when the semiconductor material itself has a high dielectric breakdown strength, the withstand voltage can be ensured even if the drift layer to retain the withstand voltage is made thinner. Therefore, for example, by making the drift layer thinner and increasing the impurity concentration, the on-resistance of the power semiconductor element can be reduced.

In other words, wide band gap power semiconductor elements are advantageous in that it is possible to achieve both the improvement in withstand voltage and the reduction in on-resistance which are in a trade-off relationship. Therefore, wide band gap power semiconductor elements are expected to be semiconductor elements capable of achieving high performance.

Examples of semiconductor materials with a band gap larger than that of silicon include silicon carbide (SiC), gallium nitride (GaN), gallium oxide (Ga2O3), and diamond. The following descriptions will be given focusing on silicon carbide.

Single crystals made of silicon carbide (hereinafter referred to as silicon carbide single crystals) are manufactured by using, for example, the sublimation method or the vapor phase method. The sublimation method is a method of manufacturing silicon carbide single crystals by sublimating a silicon carbide powder material at a high temperature of about 2400□ C. and then recrystallizing it. In addition, for example, the solution method can also be used. The solution method is a method of manufacturing silicon carbide single crystals by contacting a seed crystal attached to the tip of a shaft with a solution containing carbon and silicon in a crucible and pulling up the shaft while growing silicon carbide single crystals on the seed crystal.

The manufactured silicon carbide single crystal is taken out as an ingot. The ingot is then sliced to obtain silicon carbide substrates. Power semiconductor elements are formed on the silicon carbide substrate thus obtained.

When forming power semiconductor elements, it is necessary to form a drift layer for making the power semiconductor elements function. For this reason, an epitaxial layer that functions as a drift layer is formed on the silicon carbide substrate. In other words, the silicon carbide substrate on which an epitaxial layer is formed is used to form power semiconductor elements.

### Studies for Improvement

For example, in the substrate, a sloped portion referred to as a “beveling portion” is formed in order to suppress the occurrence of cracking or chipping at the edge of the substrate.

In the following description, a silicon carbide substrate will be used as an example of the substrate.

As mentioned above, an epitaxial layer may be formed on a surface of a silicon carbide substrate. At this time, a sloped portion referred to as a “beveling portion” connected to the surface is formed at the edge of the silicon carbide substrate, and the epitaxial layer is formed not only on the surface of the silicon carbide substrate but also on the sloped portion connected to the surface. The sloped portion is formed by, for example, a polishing technique, but the surface roughness of the sloped portion is high. For this reason, the epitaxial layer formed on the sloped portion is likely to have failures. This point will be described below.

For example, when an epitaxial layer is grown by the epitaxial growth method (for example, CVD (Chemical Vapor Deposition) layer formation), the silicon carbide substrate is exposed to a high-temperature atmosphere of about 2000□ C. In this case, not only the layer forming action but also etching action referred to as “thermal etching” works due to the high-temperature atmosphere. As a result, in the sloped portion with high surface roughness, the surface unevenness becomes larger due to “thermal etching”, and defects are likely to occur starting from the unevenness. In other words, defects are likely to occur in the epitaxial layer formed on the sloped portion with high surface roughness, and the defect density of the epitaxial layer formed on the surface of the silicon carbide substrate increases starting from these defects in some cases.

Also, in the silicon carbide substrate, epitaxial growth is performed by step-flow growth in the <11-20> direction. Therefore, the epitaxial layer is formed non-uniformly and in an irregular shape on the sloped portion, and thus defects are likely to occur in some cases.

From the foregoing, due to the propagation of defects generated in the sloped portion, the defect density of the epitaxial layer formed on the surface of the silicon carbide substrate increases, which may lead to failures in the epitaxial layer. In other words, the presence of the sloped portion with high surface roughness may cause failures in the epitaxial layer formed on the surface of the silicon carbide substrate.

Namely, defects generated in the sloped portion extend to the epitaxial layer formed on the surface (main surface) of the silicon carbide substrate in some cases. In this case, if there is a defect extending to the epitaxial layer, a semiconductor device, for example, a power semiconductor element using an epitaxial layer as a drift layer may have failures.

### Usefulness of Reclaimed Substrate

As described above, the defect density in the epitaxial layer does not meet a predetermined standard in some cases. In other words, failures may occur in the epitaxial layer formed on the silicon carbide substrate. In this respect, when the epitaxial layer formed on the silicon carbide substrate has failures even though there is no problem with the silicon carbide substrate, discarding the whole silicon carbide substrate including the epitaxial layer having failures is not appropriate from the viewpoint of effective use of resources.

Therefore, reuse of the silicon carbide substrate remaining after removing the epitaxial layer having failures formed on the silicon carbide substrate has been studied. In other words, an attempt of reusing the silicon carbide substrate by removing the epitaxial layer having failures formed on the silicon carbide substrate and then forming a new epitaxial layer on this silicon carbide substrate has been studied. According to this attempt, since the problem-free silicon carbide substrate can be reused as a reclaimed substrate, not only the effective use of resources but also the reduction in manufacturing costs of semiconductor devices and power semiconductor devices manufactured by reusing the silicon carbide substrate can be achieved. Therefore, reusing the silicon carbide substrate is useful from the viewpoint of the effective use of resources and the reduction in manufacturing costs of semiconductor devices and power semiconductor devices.

### Studies on Reclaimed Substrate

However, even in the reclaimed substrate, if the surface roughness of the sloped portion referred to as the “beveling portion” is high, failures in the epitaxial layer are likely to occur as with a bare substrate (virgin substrate) before reclaiming as described in the “Studies for Improvement” above. Specifically, even when a reclaimed substrate is obtained by removing the epitaxial layer having failures formed on a bare substrate, if the surface roughness of the sloped portion formed in this reclaimed substrate is high, failures are likely to occur also in the epitaxial layer formed again on the reclaimed substrate. In other words, even when a reclaimed substrate is obtained, if the structure is such that failures are likely to occur in the epitaxial layer formed again on the reclaimed substrate, there is no point in using the reclaimed substrate. Therefore, when manufacturing a reclaimed substrate, ingenuity for suppressing the occurrence of failures in the epitaxial layer formed again on the reclaimed substrate is desired.

For example, a “beveling portion” is formed also in a bare substrate. As a result, even when an epitaxial layer is formed on a bare substrate, “thermal etching” occurs in the “beveling portion” with a high surface roughness. However, since the number of times when the reclaimed substrate is exposed to high temperature is larger than that of a bare substrate, the degree of unevenness caused by “thermal etching” becomes higher in the reclaimed substrate. Therefore, when an epitaxial layer is formed on a reclaimed substrate, failures are more likely to occur in the epitaxial layer than when an epitaxial layer is formed on a bare substrate. For this reason, it is desirable to suppress failures in the epitaxial layer particularly in the case of the reclaimed substrate.

Furthermore, when an epitaxial layer is formed on a front surface of a bare substrate, a back surface of the bare substrate is placed on, for example, a susceptor. At this time, if the epitaxial growth atmosphere gets around, a convex portion may be formed on the back surface of the bare substrate, or a concave portion may be formed on the back surface of the bare substrate due to “thermal etching” acting on a small gap between the susceptor and the back surface of the bare substrate. As a result, unevenness is formed on the back surface of the bare substrate in some cases.

Then, when a reclaimed substrate is manufactured from such a bare substrate, unevenness is formed on the back surface of the reclaimed substrate. In this state, if the back surface of the reclaimed substrate is placed on a susceptor to grow an epitaxial layer again on the front surface of the reclaimed substrate, the posture of the reclaimed substrate when the epitaxial layer is grown becomes unstable due to the reduced flatness of the back surface. As a result, the quality of the epitaxial layer may be degraded. Furthermore, there is a possibility that the reclaimed substrate comes off the susceptor. Therefore, when manufacturing a reclaimed substrate, ingenuity for improving the flatness of the back surface of the reclaimed substrate is also desired.

Thus, an ingenuity for obtaining highly reliable reclaimed substrate is applied in this embodiment. The technical idea in this embodiment with this ingenuity will be described below.

### Method of Manufacturing Reclaimed Substrate in this Embodiment

First, as illustrate in FIG. 1, a bare substrate 100 made of, for example, a silicon carbide substrate is prepared. This bare substrate 100 has a front surface 1 which is a first main surface and a back surface 2 which is a second main surface located on an opposite side of the first main surface. Also, at an edge of the bare substrate 100, a sloped portion 3 connected to the front surface 1 and a sloped portion 4 connected to the back surface 2 are formed. Here, for example, a surface roughness of the sloped portion 3 is higher than a surface roughness of the front surface 1. Similarly, a surface roughness of the sloped portion 4 is higher than a surface roughness of the back surface 2.

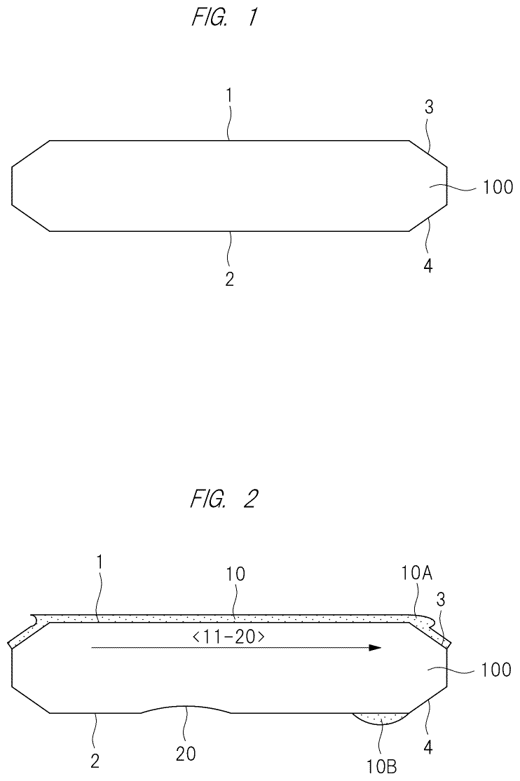

Next, as illustrated in FIG. 2, an epitaxial layer 10 made of silicon carbide is formed on the front surface 1 and the sloped portion 3 of the bare substrate 100 by using, for example, the epitaxial growth method. At this time, the epitaxial growth is performed by step-flow growth in the <11-20> direction. Therefore, the epitaxial layer 10 is formed non-uniformly and in an irregular shape on the sloped portion 3, and thus, a convex shape 10A is formed on the sloped portion 3 in some cases.

Also, as illustrated in FIG. 2, the epitaxial layer 10 is formed so as to wrap around to the back surface 2 of the bare substrate 100 in some cases, so that an attachment 10B made of the epitaxial layer 10 attached to the back surface 2 of the bare substrate 100 may be formed.

Further, as illustrated in FIG. 2, when forming the epitaxial layer 10, the back surface 2 of the bare substrate 100 is placed on a susceptor. At this time, a small gap is formed between the back surface of the bare substrate 100 and the susceptor in some cases, and a high-temperature atmosphere may enter this small gap, causing “thermal etching” to proceed. As a result, a concave portion 20 due to “thermal etching” may be formed on the back surface 2 of the bare substrate 100.

In this way, the epitaxial layer 10 can be formed on the front surface 1 of the bare substrate 100. Here, due to the occurrence of defects caused by the convex shape 10A formed on the sloped portion 3, for example, the defect density of the epitaxial layer 10 formed on the front surface 1 exceeds a threshold (prescribed value) in some cases. In this case, the epitaxial layer 10 having failures is formed on the front surface 1 of the bare substrate 100. Consequently, in this case, a reclaimed substrate is manufactured from the bare substrate 100 by removing the epitaxial layer 10 having failures formed on the bare substrate 100. The manufacturing process of the reclaimed substrate will be described below.

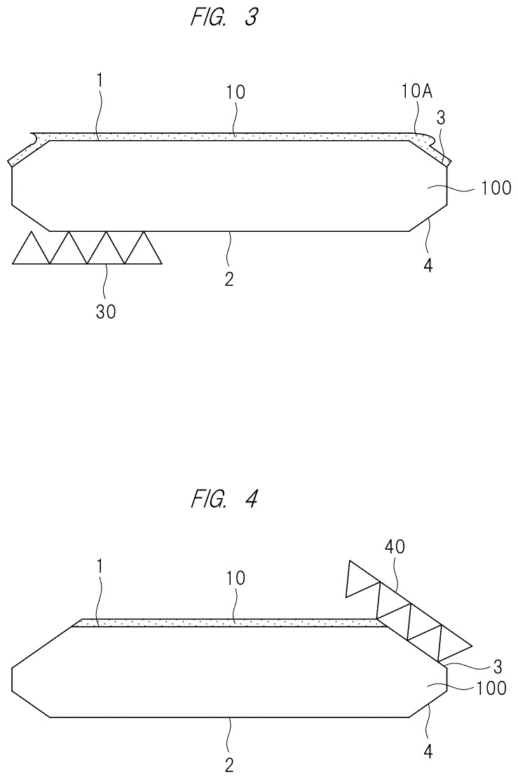

As illustrated in FIG. 3, for example, the back surface 2 of the bare substrate 100 is polished by a polishing device 30. In this way, the attachment 10B attached to the back surface 2 of the bare substrate 100 is removed, and the concave portion 20 formed on the back surface 2 is flattened. As a result, according to this embodiment, the flatness of the back surface 2 of the bare substrate 100 is improved.

Next, as illustrated in FIG. 4, for example, the epitaxial layer 10 formed on the sloped portion 3 is removed and the surface of the sloped portion 3 is ground by a grinding device 40 using a grindstone. In this way, according to this embodiment, the surface roughness of the sloped portion 3 is reduced. In other words, the flatness of the surface of the sloped portion 3 is improved. Specifically, in this embodiment, the sloped portion 3 is ground such that the surface roughness of the sloped portion 3 is less than 200 nm (Ra<200 nm).

Here, the surface roughness mentioned in this specification means “Ra”. “Ra” is a parameter in the height direction referred to as “arithmetic mean roughness”. “Ra” is obtained by extracting a part of the roughness curve measured by a roughness meter over a reference length and expressing the unevenness of that section as a mean value. Since “Ra” uses a mean value, it is less susceptible to the influence of a single prominent scratch and has the advantage of being able to provide stable results in evaluating surface roughness.

Furthermore, additional polishing is performed on the surface of the sloped portion 3 whose surface roughness is less than 200 nm. Specifically, after grinding by the grinding device 40 using a grindstone in the previous step, it is further polished (edge polishing). In this case, the sloped portion 3 is polished such that the surface roughness of the sloped portion 3 is less than 1 nm (Ra<1 nm). In this way, the flatness of the surface of the sloped portion 3 is further improved.

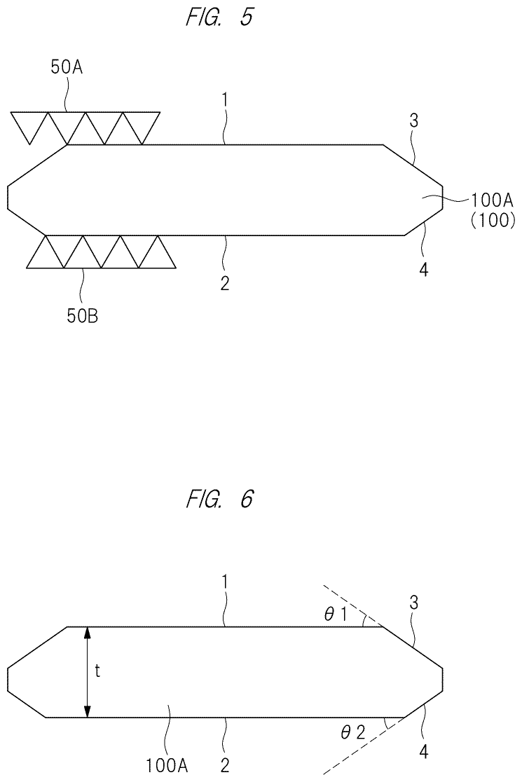

Subsequently, as illustrated in FIG. 5, for example, the epitaxial layer 10 having failures formed on the front surface 1 of the bare substrate 100 is removed by a polishing device 50A. At this time, the back surface 2 of the bare substrate 100 may also be polished using a polishing device 50B.

In this way, a reclaimed substrate 100A can be reclaimed from the bare substrate 100. Thereafter, a new epitaxial layer is formed on the front surface 1 of the reclaimed substrate 100A. As described above, even if the epitaxial layer 10 having failures is formed on the front surface 1 of the bare substrate 100, the reclaimed substrate 100A can be manufactured by removing the epitaxial layer 10 having failures.

### Features of Manufacturing Method in this Embodiment

Next, features of the manufacturing method in this embodiment will be described.

The first feature of the manufacturing method is that the back surface 2 of the bare substrate 100 is polished by the polishing device 30 or the like as illustrated in FIG. 2 and FIG. 3. In this way, the attachment 10B illustrated in FIG. 2 can be removed, and the concave portion 20 formed on the back surface 2 can be flattened. As a result, according to the first feature of the manufacturing method, the flatness of the back surface 2 of the bare substrate 100 can be improved. This means that the flatness of the back surface 2 can be finally improved in the reclaimed substrate 100A illustrated in FIG. 5. In other words, according to the first feature of the manufacturing method, the flatness of the back surface 2 of the reclaimed substrate 100A can be improved. As a result, when an epitaxial layer is formed again on the reclaimed substrate 100A, the back surface 2 of the reclaimed substrate 100A can be stably placed on a susceptor because the flatness of the back surface 2 is improved according to this embodiment.

Next, the second feature of the manufacturing method is that the epitaxial layer 10 formed on the surface of the sloped portion 3 is removed and the surface of the sloped portion 3 is ground by the grinding device 40 as illustrated in FIG. 4. In this way, it is possible to reduce the surface roughness of the sloped portion 3 in the reclaimed substrate 100A. As a result, the formation of surface unevenness due to “thermal etching” when a new epitaxial layer is formed on the front surface 1 of the reclaimed substrate 100A can be suppressed.

Thus, by implementing the second feature of the manufacturing method, the occurrence of defects due to the high surface roughness of the sloped portion 3 can be suppressed. Specifically, according to the second feature of the manufacturing method, defects are less likely to occur in the new epitaxial layer formed on the sloped portion 3, and the defect density of the epitaxial layer formed on front surface 1 of the reclaimed substrate 100A can be reduced. In other words, by implementing the second feature of the manufacturing method in this embodiment, the quality of the epitaxial layer formed on the front surface 1 of the reclaimed substrate 100A can be improved.

Furthermore, the fact that the formation of surface unevenness due to “thermal etching” is suppressed when a new epitaxial layer is formed on the front surface 1 of the reclaimed substrate 100A means that the occurrence of foreign matters due to the unevenness can also be suppressed. In this case, for example, when the epitaxial layer 10 having failures formed on the front surface 1 is removed by the polishing device 50A as illustrated in FIG. 5, the occurrence of scratches due to the adhesion of foreign matters to the front surface 1 can be suppressed.

As a result, the failure rate of the epitaxial layer newly formed on the front surface 1 of the reclaimed substrate 100A can be reduced, so that the manufacturing cost of the power semiconductor element can also be reduced.

Therefore, cracking and chipping in the reclaimed substrate 100A can be suppressed according to the first feature of the manufacturing method, and the defect density of the epitaxial layer can be reduced according to the second feature of the manufacturing method. As a result, the reliability of the reclaimed substrate 100A can be improved according to this embodiment.

### Structure of Reclaimed Substrate in this Embodiment

Next, the structure of the reclaimed substrate manufactured by the above-described manufacturing method will be described.

FIG. 6 is a diagram illustrating the structure of the reclaimed substrate 100A.

In FIG. 6, the reclaimed substrate 100A has the front surface 1, the back surface 2 located on an opposite side of the front surface 1, the sloped portion 3 connected to the front surface 1, and the sloped portion 4 connected to the back surface 2. At this time, in the reclaimed substrate 100A of this embodiment, the surface roughness of the sloped portion 3 is lower than the surface roughness of the sloped portion 4. This is because the surface of the sloped portion 3 is ground by the grinding device 40 as illustrated in FIG. 4. In particular, the surface roughness of the sloped portion 3 is less than 200 nm. Furthermore, when additional polishing (edge polishing) is performed on the surface of the sloped portion 3 whose surface roughness is less than 200 nm, the surface roughness of the sloped portion 3 becomes less than 1 nm. Then, when an angle between the front surface 1 and the sloped portion 3 is defined as a slope angle θ1 and an angle between the back surface 2 and the sloped portion 4 is defined as a slope angle θ2 as illustrated in FIG. 6, it is desirable that the slope angle θ1 is smaller than the slope angle θ2.

The slope angle θ1 described above is desirably 45° or less. This is because if the slope angle θ1 is greater than 45°, the function of preventing cracking or chipping of the reclaimed substrate 100A by the sloped portion 3 which is the “beveling portion” is reduced.

On the other hand, it is desirable that the slope angle θ1 is equal to or greater than the value given by the following equation.

θ1≥0.04t+0.

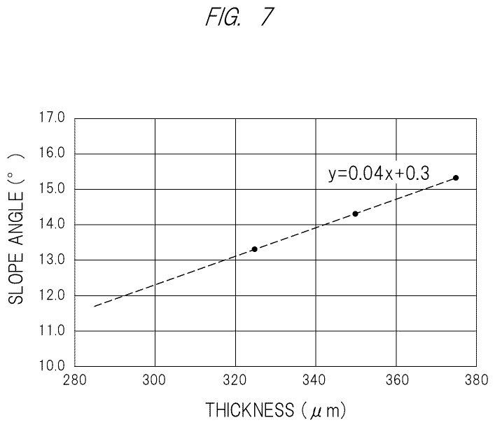

Here, t represents the thickness (μm) of the reclaimed substrate 100A. Note that FIG. 7 illustrates the above equation showing the relationship between the slope angle (°) of the sloped portion 3 and the thickness (μm) of the reclaimed substrate 100A.

When the reclaimed substrate 100A has the slope angle given by the above equation, the reclaimed substrate 100A satisfies the “SEMI standard”. In other words, the inventors have newly found that the sloped portion 3 of the reclaimed substrate 100A complies with the “SEMI standard” when the slope angle θ1 of the sloped portion 3 has the value that satisfies the above equation. Therefore, in this embodiment, by grinding or polishing the sloped portion 3 so as to have the slope angle θ1 that satisfies the above equation, the reclaimed substrate 100A having the slope angle θ1 that complies with the “SEMI standard” can be obtained.

### Scope of Application of Technical Idea in this Embodiment

The technical idea in this embodiment can be effectively applied to the manufacturing technique of the reclaimed substrate 100A. However, the technical idea in this embodiment can also be applied to, for example, the manufacturing technique of the bare substrate 100 other than that.

For example, since the surface roughness of the sloped portion 3 of the bare substrate 100 is usually high, the presence of the sloped portion 3 with high surface roughness may increase the probability that the epitaxial layer formed on the front surface of the bare substrate 100 has failures.

In this respect, when the technical idea in this embodiment is applied to the bare substrate 100, the surface roughness of the sloped portion 3 of the bare substrate 100 can be reduced. Therefore, the probability that the epitaxial layer formed on the front surface of the bare substrate 100 has failures can be reduced. In other words, by applying the technical idea in this embodiment to the bare substrate 100, the quality of the epitaxial layer formed on the front surface of the bare substrate 100 can be improved.

As described above, the technical idea in this embodiment is a useful technical idea in that it can be widely applied not only to the manufacturing technique of the reclaimed substrate 100A but also to the manufacturing technique of the bare substrate 100.

### Essence of Technical Idea

The essence of the technical idea in this embodiment is that the surface roughness of the sloped portion connected to the main surface (the surface on which the epitaxial layer is formed) of the semiconductor substrate is low.

Thus, since defects in the epitaxial layer formed on the sloped portion are reduced, defects extending to the epitaxial layer formed on the main surface are reduced, and the quality of the epitaxial layer on the main surface that functions as a drift layer can be improved.

However, by simply knowing that the surface roughness of the sloped portion is low, quantitative understanding is difficult because there is no comparison target. Therefore, in order to clearly indicate the comparison target and express the essence of the technical idea, for example, in a semiconductor substrate having a first main surface, a second main surface located on an opposite side of the first main surface, a first sloped portion connected to the first main surface, and a second sloped portion connected to the second main surface, it can be expressed that a surface roughness of the first sloped portion is lower than a surface roughness of the second sloped portion.

In this respect, the surface roughness of the first sloped portion is approximately the same as the surface roughness of the second sloped portion in general technique. In contrast, when the surface roughness of the first sloped portion is lower than that of the second sloped portion, it is possible to obtain the effect of the technical idea in this embodiment even if the degree of difference is slight. In this respect, when the degree of difference is slight, there is a possibility that the surface roughness of the first sloped portion is considered to be within the same range as the surface roughness of the second sloped portion.

Therefore, in order to make it possible to show that the surface roughness of the first sloped portion is substantially low than the surface roughness of the second sloped portion, it is desirable to quantitatively define how much lower the surface roughness of the first sloped portion must be than the surface roughness of the second sloped portion in consideration of the variation due to individual differences and the measurement accuracy of the measuring device. Therefore, in this embodiment, for example, when the surface roughness of the first sloped portion is 100 nm or more lower than the surface roughness of the second sloped portion, it can be said that “the surface roughness of the first sloped portion is lower than the surface roughness of the second sloped portion” beyond the substantially same range.

From a different viewpoint, it is also possible to express the essence of the technical idea in this embodiment described above by defining the surface roughness of the sloped portion as an absolute numerical range, without using a comparison object (see appendix). In this case, regardless of the surface roughness of the comparison object, it can be said that the surface roughness is within the range of the technical idea if the surface roughness of the sloped portion is within the absolute numerical range.

### Appendix 1

A semiconductor substrate includes a main surface on which an epitaxial layer can be formed and a sloped portion connected to the main surface, in which a surface roughness of the sloped portion is less than 200 nm.

### Appendix 2

In the semiconductor substrate described in appendix 1, the surface roughness of the sloped portion is less than 1 nm.

In the foregoing, the invention made by the inventors of this application has been specifically described based on the embodiment. However, the present invention is not limited to the embodiment above, and can be modified in various ways with the range not departing from the gist thereof.

While the present disclosure has been illustrated and described with respect to a particular embodiment thereof, it should be appreciated by those of ordinary skill in the art that various modifications to this disclosure may be made without departing from the spirit and scope of the present disclosure.

What is claimed is:

1. A semiconductor substrate comprising:
a first main surface;
a second main surface located on an opposite side of the first main surface;
a first sloped portion connected to the first main surface; and
a second sloped portion connected to the second main surface,
wherein a surface roughness of the first sloped portion is lower than a surface roughness of the second sloped portion.

2. The semiconductor substrate according to claim 1,
wherein the surface roughness of the first sloped portion is less than 200 nm.

3. The semiconductor substrate according to claim 1,
wherein the surface roughness of the first sloped portion is less than 1 nm.

4. The semiconductor substrate according to claim 1,
wherein, when an angle between the first main surface and the first sloped portion is defined as a first slope angle and an angle between the second main surface and the second sloped portion is defined as a second slope angle, the first slope angle is smaller than the second slope angle.

5. The semiconductor substrate according to claim 4,
wherein, when a thickness of the semiconductor substrate is defined as t (μm) and a value of the first slope angle is defined as θ (°), a relation of θ≥0.04t+0.3 is established.

6. The semiconductor substrate according to claim 1,
wherein the semiconductor substrate has an epitaxial layer formed on the first main surface.

7. The semiconductor substrate according to claim 1,
wherein the semiconductor substrate is a silicon carbide substrate.

8. A method of manufacturing a semiconductor substrate comprising:
(a) preparing a substrate having a first main surface, a second main surface located on an opposite side of the first main surface, a first sloped portion connected to the first main surface, and a second sloped portion connected to the second main surface;
(b) forming an epitaxial layer on the first main surface and the first sloped portion;
(c) after the (b), polishing the second main surface; and
(d) after the (c), grinding the first sloped portion.

9. The method of manufacturing the semiconductor substrate according to claim 8, further comprising
(e) after the (d), removing the epitaxial layer formed on the first main surface.

10. The method of manufacturing the semiconductor substrate according to claim 8,
wherein, after the (c), a surface roughness of the first sloped portion is less than 200 nm.

11. The method of manufacturing the semiconductor substrate according to claim 8, further comprising
(f) after the (d), polishing the first sloped portion.

12. The method of manufacturing the semiconductor substrate according to claim 11,
wherein, after the (f), a surface roughness of the first sloped portion is less than 1 nm.
